(19) United States
(12) Patent Application Publication
(10) Pub. No.: US 2026/0085219 A1
(43) Pub. Date: Mar. 26, 2026

(54) SYSTEM AND A METHOD FOR CHEMICAL MECHANICAL PLANARIZATION OF a-Si AND SiO2

(71) Applicant: FUJIMI INCORPORATED, Kiyosu-shi (JP)

(72) Inventors: Jimmy Granstrom, Tualatin, OR (US); Christopher Newman, Tualatin, OR (US)

(21) Appl. No.: 19/204,306

(22) Filed: May 9, 2025

Related U.S. Application Data
(60) Provisional application No. 63/698,513, filed on Sep. 24, 2024.

(51) Int. Cl. C09K 3/14; H01L 21/306

(52) U.S. Cl. CPC C09K 3/1463; H10P 52/402

(57) ABSTRACT

Systems and methods are provided for chemical mechanical planarization a-Si and SiO₂ substrates. The polishing composition is acidic and includes a morpholine compound including a heteroatom substituent at a nitrogen atom of the morpholine compound, and an abrasive. The polishing composition non-selectively removes both a-Si and SiO₂.

### CROSS REFERENCE TO RELATED APPLICATIONS

The present application claims priority to U.S. Provisional Application No. 63/698,513, entitled “SYSTEM AND METHOD FOR CHEMICAL MECHANICAL PLANARIZATION OF a-Si AND SiO₂”, and filed on Sep. 24, 2024. The entire contents of the above-listed application are hereby incorporated by reference for all purposes.

### FIELD

The present description relates generally to compositions and preparation methods for chemical mechanical planarization of a-Si and SiO₂.

### BACKGROUND/SUMMARY

Chemical mechanical planarization (CMP) is a process used in fabrication of nano and microelectronics. A polishing composition reacts chemically with a substrate being polished to facilitate removal of the substrate material. A chemical composition of the substrate being polished may vary depending on fabrication step as well as the device being fabricated. In some examples, the substrate may be amorphous silicon (a-Si) or silicon dioxide (SiO₂) deposited by tetraethyl orthosilicate (TEOS). a-Si includes Si⁰ while TEOS includes Si⁴⁺ bound to oxygen. Due to at least these differences, many conventional polishing compositions are formulated to quickly remove either a-Si or TEOS, where a polishing composition formulated to quickly remove a-Si has a very slow removal rate when used with TEOS and vice versa. The inventors herein identify a need for a polishing composition which quickly and non-selectively removes both a-Si and TEOS.

In one example, the issues described above may be at least partially addressed by a polishing composition for non-selectively removing a-Si and SiO₂, comprising a morpholine compound including a substituent at a nitrogen atom of the morpholine compound, wherein the substituent includes a heteroatom, and an abrasive, and wherein the polishing composition is acidic. In this way, the pH, abrasive, and morpholine compound of the composition work in an unexpected and synergistic way to quickly and non-selectively remove both a-Si and SiO₂.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 shows a diagram of a chemical mechanical planarization (CMP) system and a polishing composition.

FIG. 2 shows a graph of removal rate as function of the polishing composition pH.

FIG. 3 shows an illustration of an a-Si rate enhancer of the polishing composition.

FIG. 4 shows a flowchart of an example of a method for CMP using the polishing composition.

FIG. 5 shows examples of the a-Si rate enhancer of the polishing composition.

### DETAILED DESCRIPTION

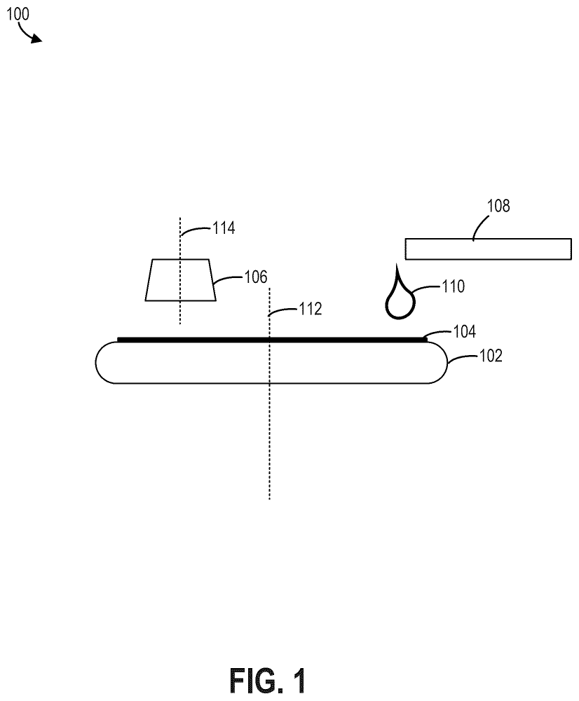

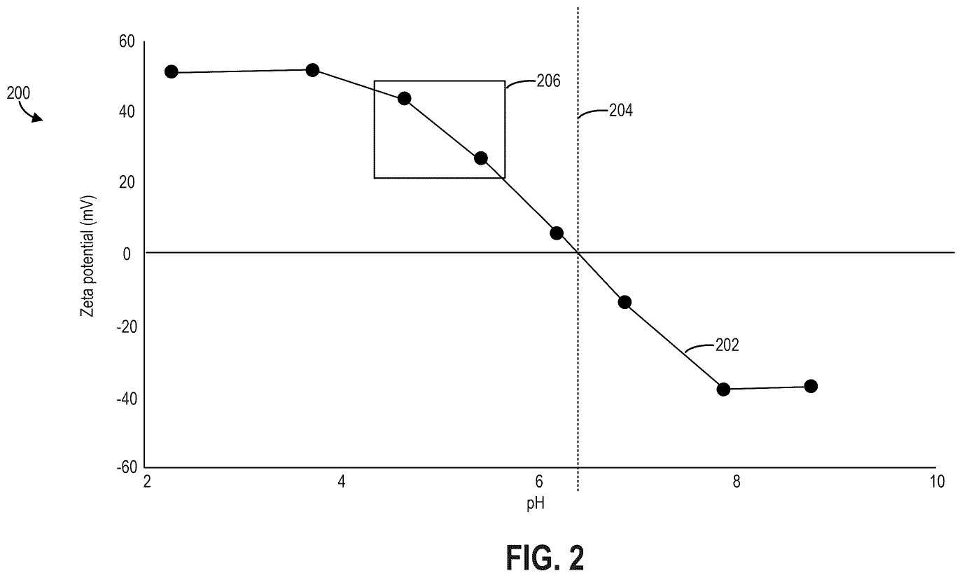

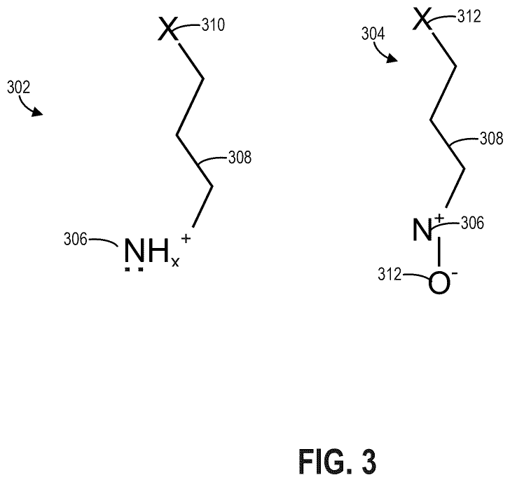

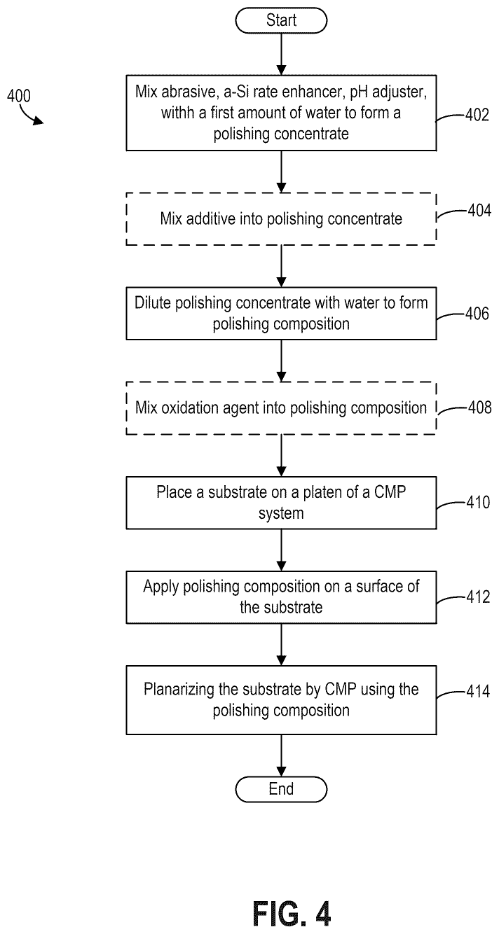

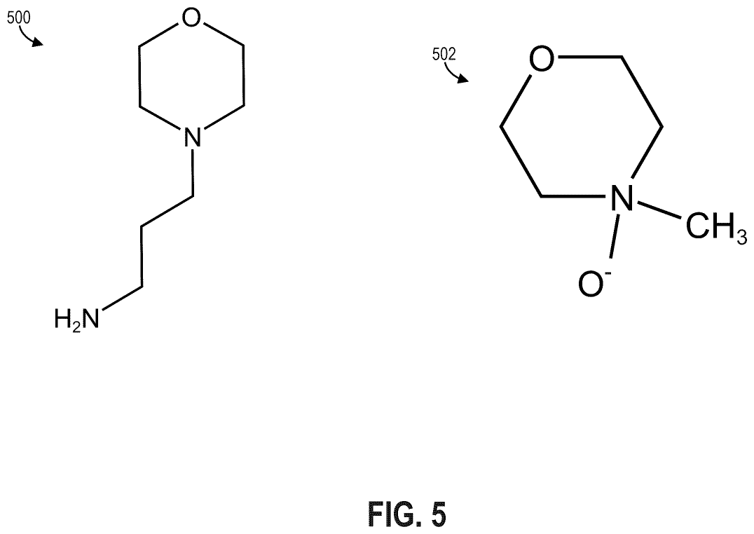

The following description relates to a polishing composition and methods for non-selective chemical mechanical planarization (CMP) of both amorphous silicon (a-Si) and silicon dioxide deposited by tetraethyl orthosilicate, the silicon dioxide formed therefrom is herein referred to as TEOS. The polishing composition may be used in a CMP system, such as the CMP system shown in FIG. 1. Components of the polishing composition may work together to quickly and non-selectively polish both a-Si and TEOS. The polishing composition may include an a-Si rate enhancer, an abrasive, and a pH adjuster. The abrasive may have a surface charge that may be adjusted via a pH of the polishing composition and both may be selected to non-selectively planarize a-Si and TEOS as shown in FIG. 2. Even with the selected abrasive and pH, a rate of TEOS removal may be higher than a rate of a-Si removal. An a-Si rate enhancer, shown in FIG. 3, may interact with the abrasive and a-Si. In some examples, the a-Si rate enhancer may be a N-substituted morpholine compound, examples of which are shown in FIG. 5. The polishing composition may be used as described in the flowchart of FIG. 4 to both quickly and non-selectively planarize a-Si and TEOS.

Briefly, an example of a portion of a CMP system 100 is shown in FIG. 1. The portion of the CMP system 100 shows a platen 102 supporting a polishing pad 104. The platen 102 may be configured to rotate in a first direction about first rotational axis 112. A polishing pad 104 may be in face sharing contact with the platen and may be rotated by the platen. A wafer holder 106 may be configured to hold a wafer, substrate or other polishing object in an orientation to bring a layer to be removed/planarized in face sharing contact with polishing pad 104. Wafer holder 106 may be configured to rotate about axis 114, thereby also rotating the polishing object. The platen 102 and wafer holder 106 may be configured to rotate in the same direction. Wafer holder 106 may be further configured to bring the polishing object in contact with polishing pad 104 with a controlled contact pressure. A supply system 108 may be configured to deliver a polishing composition 110 to a surface of polishing pad 104 at a controlled flow rate. In this way the polishing composition 110 may be distributed to an interface between the polishing object and polishing pad 104. The polishing composition may be configured to non-selectively and quickly remove material of the polishing object (e.g., the substrate) when the polishing object is a-Si and when the polishing object is TEOS.

The polishing composition, such as polishing composition 110, may be an aqueous composition including water, an abrasive, a pH adjuster and an a-Si rate enhancer. The abrasive particles may be nanoparticles. As one example, a mean particle diameter of the abrasive nanoparticles may be more than 10 nm. As one example, a mean particle diameter of the abrasive nanoparticles may be more than 20 nm. As one example, a mean particle diameter of the abrasive nanoparticles may be more than 30 nm. As one example, a mean particle diameter of the abrasive nanoparticles may be more than 50 nm. As one example, a mean particle diameter of the abrasive nanoparticles may be less than 200 nm. As one example, a mean particle diameter of the abrasive nanoparticles may be less than 150 nm. As one example, a mean particle diameter of the abrasive nanoparticles may be less than 120 nm. As one example, a mean particle diameter of the abrasive nanoparticles may be less than 100 nm. As one example, a mean particle diameter of the abrasive nanoparticles may be in the range of 10 nm to 250 nm. As one example, a mean particle diameter of the abrasive nanoparticles may be in the range of 10 nm to 200 nm. As one example, a mean particle diameter of the abrasive nanoparticles may be in the range of 15 nm to 150 nm. As one example, a mean particle diameter of the abrasive nanoparticles may be in the range of 20 nm to 120 nm. As one example, a mean particle diameter of the abrasive nanoparticles may be in the range of 30 nm to 100 nm. As one example, a mean particle diameter of the abrasive nanoparticles may be in the range of 50 nm to 80 nm. As one example, a mean particle diameter of the abrasive nanoparticles may be about 70 nm.

The abrasive particle may be formed of silica particles. Additionally or alternatively, the abrasive particles may be formed by one or more of inorganic material, organic material, and organic-inorganic composite material. Examples thereof include the abrasive formed of any of the following: oxide such as alumina, fumed silica, colloidal silica, titania, ceria, zirconia, chromium oxide, magnesium oxide, manganese dioxide, zinc oxide, iron oxide; nitride such as silicon nitride and boron nitride; carbide such as silicon carbide and boron carbide; diamond; and carbonates such as calcium carbonate and barium carbonate; particles coated therewith; composites thereof; mixtures thereof. In some examples the abrasive may have a surface charge as measured by zeta potential. Zeta potential of the abrasive can be measured by Zetasizer™ manufactured by Malvern. The abrasive particles may be cationic modified particles and/or may have a positive zeta potential. In one example, the abrasive particles may be cationic silica particles. The cationic silica particles may be amino group modified silica particles or quaternary ammonium group modified silica particles. The cationic silica particles may be manufactured by mixing a dispersion containing silica and a solution containing a silane coupling agent having a cationic group (for example, amino group or quaternary ammonium group) at a predetermined temperature for a predetermined time. Examples of the silane coupling agent used include 3-aminopropyltrimethoxysilane, 3-aminopropyltriethoxysilane, 3-aminopropyldimethoxymethylsilane, 3-(2-aminoethylamino)propyltrimethoxysilane, 3-(2-aminoethylamino)propyltriethoxysilane, 3-(2-aminoethylamino)propyldimethoxymethylsilane, 3-aminopropyldimethoxyethylsilane, trimethoxy[3-(methylamino)propyl]silane, trimethoxy[3-(phenylamino)propyl]silane, [3-(N,N-dimethylamino)propyl]trimethoxysilane, [3-(6-aminohexylamino)propyl]trimethoxysilane, N-methyl-3-(triethoxysilyl) propan-1-amine, N-[3-(trimethoxysilyl)propyl]butan-1-amine, and bis[(3-trimethoxysilyl)propyl]amine. The silane coupling agent is more preferably at least one selected from the group consisting of 3-aminopropyltrimethoxysilane, 3-aminopropyltriethoxysilane, 3-(2-aminoethylamino)propyldimethoxymethylsilane, 3-aminopropyldimethoxyethylsilane, trimethoxy[3-(methylamino)propyl]silane, trimethoxy[3-(phenylamino)propyl]silane, [3-[3-(6-aminohexylamino)propyl]trimethoxysilane, N-methyl-3-(triethoxysilyl) propan-1-amine, N-[3-(trimethoxysilyl)propyl]butan-1-amine, and bis[(3-trimethoxysilyl)propyl]amine.

A pH adjuster may be an acid included to adjust a pH of the polishing composition to a desired level. The pH of the polishing composition may be adjusted to be acidic, having a pH of less than 7.0. As a further example, the pH of the polishing solution may be adjusted to be in a range of 2.5 to 5.5. In further examples, the pH of the polishing solution may be in a range of 4.5-5.5. The pH adjuster may be an acid or base, depending on if adjustment is to (N,N-dimethylamino)propyl]trimethoxysilane, increase or decrease pH. As one example the pH adjuster may be an inorganic acid such as sulfuric acid, nitric acid, boric acid, phosphoric acid, or the like. As a further example, the pH adjuster may be an organic acid such as carboxylic acids, organic sulfuric acids, or the like. As an additional example, the pH adjuster may be a base, including hydroxides of an alkali metal such as potassium hydroxide. As a further example, the pH adjuster may be an amine or a quaternary ammonium salt. In some examples, the pH adjuster may be a combination two or more of the above listed acids and/or bases.

Turning now to FIG. 2, it shows a graph 200 of zeta potential of a cationic silica abrasive as a function of pH of the polishing composition. A plot 202 corresponds to zeta potential of silica abrasive particles. A line 204 corresponds to an isoelectric equivalence point of the silica abrasive particles. At very low pH (e.g., pH<2.5) the cationic silica abrasive particles may have a highly positive zeta potential resulting in a high TEOS removal rate but a low a-Si removal rate. At basic pH, (e.g., pH>7) the silica abrasive particles may have a negative zeta potential and a removal rate of a-Si may be high but the removal rate of TEOS may be low. In order to non-selectively remove TEOS and a-Si with the polishing composition, an acidic pH may be used. The pH range of 2.5-5.5 may be acidic enough result in positive zeta potential of the abrasive to remove TEOS without overly hindering removal of a-Si. Further, a pH range shown by box 206 indicating between pH 4.5 and pH 5.5 may be a balance between removal rates of TEOS and a-Si.

The a-Si rate enhancer may be included in the polishing composition to further increase a rate of a-Si removal under acidic conditions in the presence of cationic abrasive. Turning now to FIG. 3, an illustration of a-Si rate enhancer is shown. FIG. 3 shows a general concept of an a-Si rate enhancer. First a-Si rate enhancer 302 may include a positive or neutral nitrogen atom 306. The nitrogen may be bonded to an alkyl group 308 and alkyl group 308 may be further bonded to hydrophilic group 310. In an exemplary embodiment, hydrophilic group 310 is an oxygen. The second a-Si rate enhancer 304 may include the nitrogen atom 306, alkyl group 308, and hydrophilic group 310 and may further include an oxygen 312 bound to the nitrogen atom 306. The oxygen 312 may be negatively charged at a pH of the polishing composition. In some examples, the nitrogen atom may be further bonded to an oxygen providing a nitrogen oxide group.

In one example, a ratio of hydrophobic atoms (e.g., carbons) to a total of hydrophilic atoms (e.g., nitrogen and oxygen) may be in range of 1.7 to 3. If the a-Si rate enhancer is too hydrophobic the a-Si rate enhancer may not be dissolved in the aqueous solvent of the polishing composition. If the a-Si rate enhancer is too hydrophilic the molecule may stay in the aqueous phase and not interact with a-Si substrate. In some examples, the a-Si rate enhancer may include no more than one positively charged, non-tertiary nitrogen atom.

In an exemplary embodiment the a-Si rate enhancer may be a morpholine compound. For example, the a-Si rate enhancer may be an N-substituted morpholine compound having substituents including a heteroatom (e.g., N and/or O) linked at the nitrogen atom of the morpholine compound. The N-substituted morpholine compound may have one or more substituents. The substituent may be a heteroatom (e.g., N and/or O), an alkyl group, or an alkyl group may be substituted with a functional group. The alkyl group may be a linear or branched alkyl group. The alkyl group may have 1 to 5 carbon atoms. In one example, the substituent heteroatom is limited to oxygen. In some examples, the substituent heteroatom consists essentially of oxygen. In one example, the a-Si rate enhancer may be 3-morpholinopropylamine (APM). A chemical structure of APM 500 is shown in FIG. 5. APM may be an example of first a-Si rate enhancer 302 shown in FIG. 3. APM may include a primary amine group which may provide the free electrons or may be positively charged in the pH range of the polishing composition. In an alternate example, the substituent heteroatom is nitrogen or is limited to nitrogen. In some examples, the substituent heteroatom consists essentially of nitrogen. The a-Si rate enhancer may be 4-methylmorpholine 4-oxide (NMMO). A chemical structure of NMMO 502 is shown in FIG. 5. NMMO may be an example of second a-Si rate enhancer 304 shown in FIG. 3 and the 4-oxide group may be negatively charged in the polishing composition. The oxygen bound to the nitrogen may be negatively charged in the pH range of the polishing composition and may help oxidize the a-Si substrate.

In some examples the polishing composition may further include an oxidizing agent. For example, the oxidizing agent may be one or more of peroxide such as hydrogen peroxide; nitrate compounds such as nitric acid, salts thereof including iron nitrate, silver nitrate, aluminum nitrate, and complexes thereof including cerium ammonium nitrate; persulfate compounds such as persulfuric acid including peroxomonosulfuric acid, peroxodisulfuric acid and the like, and salts thereof including persulfate ammonium, persulfate potassium and the like; chlorine-containing compounds such as chloric acid and salt thereof, perchioric acid and salt there of including potassium perchlorate; bromine-containing compounds such as bromic acid and salt thereof including potassium bromate; iodine-containing compounds such as iodic acid and salts thereof including ammonium iodate, and periodic acid and salts thereof including sodium periodate and potassium periodate; ferric acids such as ferric acid and salts thereof including potassium ferrate; permanganic acids such as permanganic acid and salts thereof including sodium permanganate and potassium permanganate; chromic acids such as chromic acid and salts thereof including potassium chromate and potassium dichromate; vanadic acids such as vanadic acid and salts thereof including ammonium vanadate, sodium vanadate, and potassium vanadate; nuhenic acids such as perruthenic acid and salts thereof; molybdic acids such as molybdic acid and salts thereof including ammonium molybdate and disodium molybdate; rhenium acids such as perrhenic acid and salts thereof; and tungstic acids such as tungstic acid and salts thereof including disodium tungstate. In some examples, wherein the a-Si rate enhancer includes an N—O group (e.g., NMMO), the a-Si rate enhancer may also act as an oxidizing agent in the polishing composition.

In some examples an additive may be included in the polishing composition. In some examples, the additive includes antiseptic agents, antifungal agents, biocides (e.g., isothiazolinones such as methylisothiazolinone (“MIT”), benzisothiazolinone (“BIT”), 2-methyl-4-isothiazolin-3-one, etc.), dispersants (additives that improve the redispersibility of abrasive grains that have once settled), electrical conductivity adjusting agents (additives that adjust the electric conductivity of the polishing composition), abrasive grains other than the abrasive grains mentioned above, chelating agents, reducing agents, polymers, surfactant and dissolved gases.

Turning now to FIG. 4, a flowchart of a method 400 for non-selectively removing a-Si and TEOS by CMP using a polishing composition, such as the polishing composition described above is shown. At 402, method 400 include mixing an abrasive, a-Si rate enhancer, pH adjuster with a first amount of water to form a polishing concentrate. The a-Si rate enhancer may be a morpholine compound as described above. Further, the pH adjuster and abrasive may be as described above. The polishing concentrate may be mixed until the water soluble components are fully dissolved and the non-soluble components (e.g., the abrasive) are homogeneously suspended. At 404, method 400 optionally includes mixing an additive, such as the additive described above into the polishing concentrate.

A concentration of the abrasive in the polishing concentrate may be in a range of >0% up to 20% by weight. In further examples the abrasive concentration may in a range of 4% up to 15% by weight in the polishing concentrate. A concentration of the a-Si rate enhancer in the polishing concentrate may be in a range of >0% up to 5% by weight. In further examples a weight percent of the of the a-Si rate enhancer may be in a range of 0.6% up to 1.2% in the polishing concentrate. The pH adjuster may be added to the polishing concentrate as need to adjust the pH to a desired pH.

At 406, method 400 includes diluting the polishing concentrate with water to form the polishing composition. Diluting may include diluting the polishing concentrate with water in a range of 1 times up to 5 times the polishing concentrate volume.

A concentration of the abrasive in the polishing composition may be in a range of >0% up to 10% by weight. In further examples the abrasive concentration may in a range of 3% up to 7.5% by weight in the polishing composition. As one example, a concentration of the abrasive in the polishing composition may be more than 0.1%. As one example, a concentration of the abrasive in the polishing composition may be more than 0.2%. As one example, a concentration of the abrasive in the polishing composition may be more than 0.5%. As one example, a concentration of the abrasive in the polishing composition may be more than 0.7%. As one example, a concentration of the abrasive in the polishing composition may be more than 1% by weight. As one example, a concentration of the abrasive in the polishing composition may be more than 1.5% by weight. As one example, a concentration of the abrasive in the polishing composition may be more than 2% by weight. As one example, a concentration of the abrasive in the polishing composition may be more than 2.5% by weight. As one example, a concentration of the abrasive in the polishing composition may be more than 3% by weight. As one example, a concentration of the abrasive in the polishing composition may be more than 4% by weight. As one example, a concentration of the abrasive in the polishing composition may be more than 5% by weight. As one example, a concentration of the abrasive in the polishing composition may be less than 10% by weight. As one example, a concentration of the abrasive in the polishing composition may be less than 9% by weight. As one example, a concentration of the abrasive in the polishing composition may be less than 8% by weight.

A concentration of the a-Si rate enhancer in the polishing composition may be in a range of >0% up to 5% by weight. In further examples a weight percent of the of the a-Si rate enhancer may be in a range of 0.1% up to 1.5% in the polishing composition. As one example, a concentration of the a-Si rate enhancer in the polishing composition may be more than 0.01% by weight. As one example, a concentration of the a-Si rate enhancer in the polishing composition may be more than 0.02% by weight. As one example, a concentration of the a-Si rate enhancer in the polishing composition may be more than 0.05% by weight. As one example, a concentration of the a-Si rate enhancer in the polishing composition may be more than 0.07% by weight. As one example, a concentration of the a-Si rate enhancer in the polishing composition may be more than 0.1% by weight. As one example, a concentration of the a-Si rate enhancer in the polishing composition may be more than 0.15% by weight. As one example, a concentration of the a-Si rate enhancer in the polishing composition may be more than 0.2% by weight. As one example, a concentration of the a-Si rate enhancer in the polishing composition may be more than 0.25% by weight. As one example, a concentration of the a-Si rate enhancer in the polishing composition may be less than 5% by weight. As one example, a concentration of the a-Si rate enhancer in the polishing composition may be less than 4% by weight. As one example, a concentration of the a-Si rate enhancer in the polishing composition may be less than 3% by weight. As one example, a concentration of the a-Si rate enhancer in the polishing composition may be less than 2% by weight. As one example, a concentration of the a-Si rate enhancer in the polishing composition may be less than 1.5% by weight. As one example, a concentration of the a-Si rate enhancer in the polishing composition may be less than 1.2% by weight. As one example, a concentration of the a-Si rate enhancer in the polishing composition may be less than 1% by weight. As one example, a concentration of the a-Si rate enhancer in the polishing composition may be less than 0.8% by weight.

At 408, method 400 optionally includes mixing an oxidizing agent, such as hydrogen peroxide, as described above into the polishing composition. In on example, mixing the oxidizing agent may occur when diluting the polishing concentrate. If added, the oxidizing agent may be in a range of >0% up to 5% by weight in the polishing composition. In further examples the oxidizing agent may be in range of 0.5% to 3% by weight in the polishing composition. As one example, a concentration of the oxidizing agent in the polishing composition may be more than 0.1% by weight. As one example, a concentration of the oxidizing agent in the polishing composition may be more than 0.2% by weight. As one example, a concentration of the oxidizing agent in the polishing composition may be more than 0.5% by weight. As one example, a concentration of the oxidizing agent in the polishing composition may be more than 1% by weight. As one example, a concentration of the oxidizing agent in the polishing composition may be less than 5% by weight. As one example, a concentration of the oxidizing agent in the polishing composition may be less than 4% by weight. As one example, a concentration of the oxidizing agent in the polishing composition may be less than 3% by weight. As one example, a concentration of the oxidizing agent in the polishing composition may be less than 2% by weight.

Method 400 proceeds to 410 and includes placing a substrate on a platen of a CMP system, such as CMP system 100 of FIG. 1. A surface of the substrate may be formed of a-Si or TEOS. At 412, method 400 includes applying the polishing composition to the surface of the substrate. The polishing composition may be dispensed as described above with respect to FIG. 1. At 414, method 400 includes planarizing the substrate by CMP using the polishing composition. Planarizing the substrate may include placing the substrate on a platen of the CMP system as shown in FIG. 1 and applying the polishing composition to the substrate and removing material of the substrate using a CMP systems, such as the CMP system 100 FIG. 1. The substrate may be a-Si, TEOS or may include a combination of the two and SiN (Plasma enhanced SiN or Low pressure SiN). Planarizing may include quickly removing material from the substrate. Quick removal may herein refer to removal at or above a threshold rate. The threshold rate may be 700 angstroms/min. Planarizing may include non-selectively planarizing TEOS and a-Si. Non-selectively planarizing may refer to planarizing rates of a-Si and TEOS being within a desired ratio. For example, a ratio of a removal rate of a-Si to a removal rate of TEOS be in a range of 1:1 up to 1:4 for non-selective planarization. Method 400 ends.

Substrates were polished using polishing compositions demonstrating a role of components of the polishing composition in maintaining the fast and non-selective planarization of a-Si and TEOS. An a-Si substrate and a TEOS substrate were each polished under the same conditions to determine a removal rate and selectivity of the polishing composition. The a-Si and TEOS substrates tested are provided in Table 1 below.

TABLE 1
Test substrates

| Film type | Supplier | Description (bottom to top) |
|---|---|---|
| TEOS | Advantiv Technologies, Inc. | Si substrate, |
| | | 10000 angstrom TEOS |
| a-Si | Advantiv Technologies, Inc. | 5000 angstrom a-Si |

The tests further described below were carried out using one of two conditions described in Table 2.

TABLE 2
Conditions for planarizing substrates

| | |
|---|---|
| Condition 1 | Condition 2 |

| | | |
|---|---|---|
| Polisher | 200 mm Polisher | 200 mm Polisher |
| | EBARA ™ EPO | EBARA ™ EPO |
| Pad | Dow ® VP600 | Fujibo ™ OVP9500 |
| Conditioner | 3M ™ A165 | 3M ™ Nylon brush |

| Down force | 1.5 | psi | 1.5 psi-2.5 psi | |
|---|---|---|---|---|
| Platen rotation | 100 | rpm | 100 | rpm |
| Head rotation | 94 | rpm | 94 | rpm |
| Slurry | 100 | mL/min | 100 | mL/min |
| flow rate | | | | |

| | | |
|---|---|---|
| Cleaner on | H₂O | H₂O |
| platen | | |
| Cleaner on | H₂O | H₂O |
| brush box | | |

Table 3 below shows the effects of addition of an a-Si rate enhancer to the polishing composition on removal rates of a-Si and TEOS, specifically the effects NMMO and APM. Both NMMO and APM each include the desired characteristics of an a-Si rate enhancer as described above with respect to FIG. 3. The weight percents given in Table 3 are in the polishing concentrate and the dilution indicates dilution factor to reach the polishing composition from the polishing concentrate. Removal rates are provided in angstroms/min.

TABLE 3
Effects of a-Si rate enhancer on a-Si and TEOS removal rates,

| | Abrasive | | | | | | | | |
|---|---|---|---|---|---|---|---|---|---|
| | (mean particle | | | | | | | | |
| | diameter)/ | a-Si RE | | pH | | | a-Si | TEOS | |
| Slurry | (wt. %) | (wt. %) | pH | adjuster | Dilution | Condition | Rate | Rate | Ratio |
| 1 | Commercially | NMMO | 4 | KOH | 5x | 2 | 1400 | 1400 | 1.0 |
| | available | (1.2) | | | | | | | |
| | cationic silica | | | | | | | | |
| | (65 nm)/(15) | | | | | | | | |
| Ctrl-1 | Commercially | n/a | 4 | HNO₃ | 5x | 2 | 310 | 850 | 0.4 |
| | available | | | | | | | | |
| | cationic silica | | | | | | | | |
| | (65 nm)/(15) | | | | | | | | |
| 2 | Commercially | APM | 3.29 | HNO₃ | 2x | 1 | 1000 | 700 | 1.4 |
| | available | (0.6%) | | | | | | | |
| | colloidal silica* | | | | | | | | |
| | (70 nm)/(15) | | | | | | | | |
| Ctrl-2 | Commercially | n/a | 10 | KOH | 2x | 1 | 1000 | 100 | 10.0 |
| | available | | | | | | | | |
| | colloidal silica* | | | | | | | | |
| | (70 nm)/(15) | | | | | | | | |

*= PL-3 manufactured by Fuso [Fuso Chemical Co. Ltd.]

As shown in Table 3, addition of the a-Si rate enhancer may increase a removal rate of both the a-Si and TEOS, although the a-Si increased by a greater amount when the pH is acidic. In this way, the a-Si rate enhancer may contribute to both a removal rate of a-Si of at least 700 angstroms/min and non-selective removal of a-Si and TEOS.

Table 4 below shows the effects of pH on removal rate and selectivity in the presence of each of the a-Si rate enhancers. The weight percents given in Table 4 are in the polishing concentrate and the dilution indicates dilution factor to reach the polishing composition from the polishing concentrate. Removal rates are provided in angstroms/min.

TABLE 4
Effects of pH on a-Si and TEOS removal rates.

| | Abrasive | | | | | | | | |
|---|---|---|---|---|---|---|---|---|---|
| | (mean particle | | | | | | | | |
| | diameter)/ | a-Si RE | | pH | | | a-Si | TEOS | |
| Slurry | (wt. %) | (wt. %) | pH | adjuster | Dilution | Condition | Rate | Rate | Ratio |
| 3 | Commercially | NMMO | 4 | HNO₃ | 5x | 2 | 1400 | 1400 | 1.0 |
| | available | (1.2) | | | | | | | |
| | cationic silica | | | | | | | | |
| | (65 nm)/(15) | | | | | | | | |
| 4 | Commercially | NMMO | 4 | HNO3 | 5x | 2 | 1200 | 1400 | 0.9 |
| | available | (1.2) | | | | | | | |
| | cationic silica | | | | | | | | |
| | (65 nm)/(15) | | | | | | | | |
| Ctrl-3 | Commercially | NMMO | 10 | KOH | 5x | 2 | 740 | 180 | 4.1 |
| | available | (1.2) | | | | | | | |
| | cationic silica | | | | | | | | |
| | (65 nm)/(15) | | | | | | | | |
| 5 | Commercially | NMMO | 4 | HNO₃ | 1x | 1 | 1300 | 900 | 1.4 |
| | available | (0.7) | | | | | | | |
| | cationic silica | | | | | | | | |
| | (65 nm)/(5) | | | | | | | | |
| 6 | Commercially | NMMO | 5 | HNO3 | 1x | 1 | 1600 | 700 | 2.3 |
| | available | (0.7) | | | | | | | |
| | cationic silica | | | | | | | | |
| | (65 nm)/(5) | | | | | | | | |
| Ctrl-4 | Commercially | NMMO | 10 | KOH | 1x | 1 | 1300 | 45 | 28.9 |
| | available | (0.7) | | | | | | | |
| | cationic silica | | | | | | | | |
| | (65 nm)/(5) | | | | | | | | |
| 7 | Commercially | APM | 3.29 | HNO₃ | 2x | 1 | 1000 | 700 | 1.4 |
| | available | (0.6) | | | | | | | |
| | colloidal | | | | | | | | |
| | silica* | | | | | | | | |
| | (70 nm)/(15) | | | | | | | | |
| Ctrl-5 | Commercially | APM | 10 | KOH | 2x | 1 | 1000 | 100 | 10.0 |
| | available | (0.6) | | | | | | | |
| | colloidal | | | | | | | | |
| | silica* | | | | | | | | |
| | (70 nm)/(15) | | | | | | | | |
| 8 | Commercially | APM | 3.34 | HNO₃ | 2x | 2 | 800 | 820 | 1.0 |
| | available | (0.6) | | | | | | | |
| | colloidal | | | | | | | | |
| | silica* | | | | | | | | |
| | (70 nm)/(15) | | | | | | | | |
| 9 | Commercially | APM | 4.95 | HNO₃ | 2x | 2 | 1100 | 800 | 1.4 |
| | available | (0.6) | | | | | | | |
| | colloidal | | | | | | | | |
| | silica* | | | | | | | | |
| | (70 nm)/(15) | | | | | | | | |
| Ctrl-6 | Commercially | APM | 10 | KOH | 2x | 2 | 560 | 30 | 18.7 |
| | available | (0.6) | | | | | | | |
| | colloidal | | | | | | | | |
| | silica* | | | | | | | | |
| | (70 nm)/(15) | | | | | | | | |

*= PL-3 manufactured by Fuso As shown in Table 4, adjusting a pH of the polishing composition to a basic pH disproportionately decreases a removal rate for TEOS compared to a-Si. For each a-Si rate enhancer and under both removal conditions, a rate above 700 angstroms/min is measured for both a-Si and TEOS as well as a rate ratio below 4 is measured when the pH is acidic.

Table 5 below shows the effects of abrasive on removal rate and selectivity in the presence of NMMO. Both non-modified and cationic modified (Cat.) abrasives are compared. The cationic modified abrasives are prepared by mixing a dispersion containing PL-3 (colloidal silica manufactured by Fuso) and a solution containing 3-aminopropyltriethoxysilane. The weight percents given in Table 5 are in the polishing concentrate and the dilution indicates dilution factor to reach the polishing composition from the polishing concentrate. Removal rates are provided in angstroms/min.

TABLE 5
Effects of abrasive on a-Si and TEOS removal rates.

| | Abrasive | | | | | | | | |
|---|---|---|---|---|---|---|---|---|---|
| | (mean particle | | | | | | | | |
| | diameter)/ | a-Si RE | | pH | | | a-Si | TEOS | |
| Slurry | (wt. %) | (wt. %) | pH | adjuster | Dilution | Condition | Rate | Rate | Ratio |
| 10 | Cat. PL-3* | NMMO | 5.5 | HNO₃ | 1x | 1 | 720 | 420 | 1.7 |
| | (70 nm)/(4) | (1%) | | | | | | | |
| 11 | Commercially | NMMO | 5.5 | HNO₃ | 1x | 1 | 750 | 455 | 1.6 |
| | available | (1%) | | | | | | | |
| | colloidal silica* | | | | | | | | |
| | (70 nm)/(4) | | | | | | | | |
| Ctrl-7 | n/a | NMMO | 5.5 | HNO₃ | 1x | 1 | 0 | 0 | n/a |
| | | (1%) | | | | | | | |

*= PL-3 manufactured by Fuso As shown in Table 5, without abrasive (Ctrl-7) no removal of the substrate occurs. Both cationic and neutral commercially available silica are capable of removing a-Si and TEOS at desired rates and ratios. As discussed above pH may be a more important factor in controlling surface zeta potential of the abrasive and therefore the resulting removal rates.

As discussed above, the polishing composition may also optionally include an oxidizing agent. Table 6 below shows effects of adding additional oxidizing agent in combination with a non-nitro-oxide bearing (e.g., APM) a-Si rate enhancer. In the testing example, each of the slurries below include commercially available colloidal silica abrasive having a mean particle diameter of 65 nm at 15% by weight in the polishing concentrate. The weight percents given in Table 6 are in the polishing concentrate and the dilution indicates dilution factor to reach the polishing composition from the polishing concentrate. Removal rates are provided in angstroms/min.

TABLE 6
Effects of oxidizing agent on a-Si and TEOS removal rates

| | a-Si | Oxidizing | | | | | | | |
|---|---|---|---|---|---|---|---|---|---|
| | RE | agent | | pH | | | a-Si | TEOS | |
| Slurry | (wt. %) | (wt. %) | pH | adjuster | Dilution | Condition | Rate | Rate | Ratio |
| 12 | APM | n/a | 3.29 | HNO₃ | 2x | 1 | 1000 | 700 | 1.4 |
| | (0.6) | | | | | | | | |
| 13 | APM | H₂O₂ | 3.29 | HNO₃ | 2x | 1 | 1500 | 700 | 2.1 |
| | (0.6) | (4) | | | | | | | |
| Ctrl-8 | APM | H₂O₂ | 10 | KOH | 2x | 1 | 700 | 270 | 2.6 |
| | (0.6) | (2) | | | | | | | |
| 14 | APM | H₂O₂ | 3.34 | HNO₃ | 2x | 2 | 1800 | 800 | 2.3 |
| | (0.4) | (4) | | | | | | | |
| 15 | APM | H₂O₂ | 4.06 | HNO₃ | 3x | 2 | 1500 | 720 | 2.1 |
| | (0.4) | (2) | | | | | | | |
| 16 | APM | H₂O₂ | 4.65 | HNO₃ | 2x | 2 | 2400 | 700 | 3.4 |
| | (0.4) | (4) | | | | | | | |

As shown by comparing slurry 12 and slurry 13, adding an oxidizing agent under acidic conditions may increase a removal rate of both a-Si and TEOS. However, under basic conditions (see Ctrl-8) removal of both a-Si and TEOS are slower and TEOS is slowed much more than a-Si.

The technical effect of method 400 is to non-selectively remove a-Si and TEOS substrate via CMP. The prepared polishing composition includes a combination of abrasive, pH, and a-Si rate enhancer that work synergistically to quickly remove both a-Si and TEOS despite the different chemical properties of the two substrates.

The disclosure also provides support for a polishing composition for non-selectively removing a-Si and SiO₂, comprising: a morpholine compound including a substituent at a nitrogen atom of the morpholine compound, wherein the substituent includes a heteroatom, and an abrasive, and wherein the polishing composition is acidic. In a first example of the system, the heteroatom of the substituent is oxygen. In a second example of the system, optionally including the first example, the heteroatom is limited to oxygen. In a third example of the system, optionally including one or both of the first and second examples, the morpholine compound is 4-methylmorpholine 4-oxide. In a fourth example of the system, optionally including one or more or each of the first through third examples, the heteroatom is a nitrogen atom. In a fifth example of the system, optionally including one or more or each of the first through fourth examples, the morpholine compound is and 3-morpholinopropylamine. In a sixth example of the system, optionally including one or more or each of the first through fifth examples, a zeta potential of the abrasive in the polishing composition is positive. In a seventh example of the system, optionally including one or more or each of the first through sixth examples, the abrasive comprises cationic modified particles. In a eighth example of the system, optionally including one or more or each of the first through seventh examples, the abrasive comprises silica particles. In a ninth example of the system, optionally including one or more or each of the first through eighth examples, the polishing composition further comprises an oxidizing agent. In a tenth example of the system, optionally including one or more or each of the first through ninth examples, a pH of the polishing composition is between 2.5 and 5.5.

The disclosure also provides support for a polishing composition for non-selectively removing a-Si and SiO₂, comprising: 4-methylmorpholine 4-oxide, and an abrasive. In a first example of the system, an oxygen of the 4-oxide group of 4-methylmorpholine is negatively charged in the polishing composition. In a second example of the system, optionally including the first example, the polishing composition is acidic. In a third example of the system, optionally including one or both of the first and second examples, a pH of the polishing composition is between 2.5 and 5.5. In a fourth example of the system, optionally including one or more or each of the first through third examples, the abrasive is cationic silica. In a fifth example of the system, optionally including one or more or each of the first through fourth examples, the polishing composition further comprises hydrogen peroxide.

The disclosure also provides support for a method for non-selectively removing a-Si and TEOS, comprising: placing a substrate on a platen of a chemical mechanical planarization system, applying a polishing composition on a surface of the substrate, wherein the polishing composition comprises an abrasive and a morpholine compound, the morpholine compound including a substituent at a nitrogen atom of the morpholine compound, wherein the substituent includes a heteroatom, and planarizing the surface of the substrate, wherein the surface is formed of one or more of a-Si and TEOS and wherein a ratio of removal rates of a-Si to TEOS is in a range of 1:1 to 1:4. In a first example of the method, a removal rate of a-Si and a removal rate of TEOS are each at least 700 angstroms/min. In a second example of the method, optionally including the first example, a pH of the polishing composition is in a range of 2.5-5.5.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A polishing composition for non-selectively removing a-Si and SiO₂, comprising:
a morpholine compound including a substituent at a nitrogen atom of the morpholine compound, wherein the substituent includes a heteroatom; and
an abrasive, and wherein the polishing composition is acidic.

2. The polishing composition of claim 1, wherein the heteroatom of the substituent is oxygen.

3. The polishing composition of claim 1, wherein the heteroatom is limited to oxygen.

4. The polishing composition of claim 1, wherein the morpholine compound is 4-methylmorpholine 4-oxide.

5. The polishing composition of claim 1, wherein the heteroatom is a nitrogen atom.

6. The polishing composition of claim 1, wherein the morpholine compound is 3-morpholinopropylamine.

7. The polishing composition of claim 1, wherein a zeta potential of the abrasive in the polishing composition is positive.

8. The polishing composition of claim 1, wherein the abrasive comprises cationic modified particles.

9. The polishing composition of claim 1, wherein the abrasive comprises silica particles.

10. The polishing composition of claim 1, wherein the polishing composition further comprises an oxidizing agent.

11. The polishing composition of claim 1, wherein a pH of the polishing composition is between 2.5 and 5.5.

12. A polishing composition for non-selectively removing a-Si and SiO₂, comprising:
4-methylmorpholine 4-oxide; and
an abrasive.

13. The polishing composition of claim 12, wherein an oxygen of a 4-oxide group of the 4-methylmorpholine is negatively charged in the polishing composition.

14. The polishing composition of claim 12, wherein the polishing composition is acidic.

15. The polishing composition of claim 12, wherein a pH of the polishing composition is between 2.5 and 5.5.

16. The polishing composition of claim 12, wherein the abrasive is cationic silica.

17. The polishing composition of claim 12, wherein the polishing composition further comprises hydrogen peroxide.

18. A method for non-selectively removing a-Si and TEOS, comprising:
placing a substrate on a platen of a chemical mechanical planarization system;
applying a polishing composition on a surface of the substrate, wherein the polishing composition comprises an abrasive and a morpholine compound, the morpholine compound including a substituent at a nitrogen atom of the morpholine compound, wherein the substituent includes a heteroatom; and
planarizing the surface of the substrate, wherein the surface is formed of one or more of a-Si and TEOS and wherein a ratio of removal rates of a-Si to TEOS is in a range of 1:1 to 1:4.

19. The method of claim 18, wherein a removal rate of a-Si and a removal rate of TEOS are each at least 700 angstroms/min.

20. The method of claim 18, wherein a pH of the polishing composition is in a range of 2.5-5.5.
